(19) United States
(12) Patent Application Publication
(10) Pub. No.: US 2019/0242450 A1
(43) Pub. Date: Aug. 8, 2019

(54) BRAKE PAD WEAR SENSOR

(71) Applicant: TRW AUTOMOTIVE U.S. LLC, Livonia, MI (US)

(72) Inventor: XING PING LIN, West Bloomfield, MI (US)

(21) Appl. No.: 16/329,769

(22) PCT Filed: Sep. 11, 2017
(86) PCT No.: PCT/US17/50897

§ 371 Date: Mar. 1, 2019

Related U.S. Application Data
(60) Provisional application No. 62/385,573, filed on Sep. 9, 2016.

(51) Int. Cl. F16D 66/02; G01R 33/00; H04B 5/00

(52) U.S. Cl. CPC F16D 66/027; F16D 66/024; H04B 5/0037; G01R 33/00

(57) ABSTRACT

A brake pad wear sensing system for measuring brake pad wear for a vehicle disc brake system includes a brake pad wear sensor including a near field communication (“NFC”) circuit for transmitting an NFC signal and a tank circuit including a resonating component and a charge storage component. The tank circuit powers the brake pad wear sensor including the NFC circuit. The tank circuit is configured to be inductively charged in response to interrogation by a NFC device positioned within a predetermined proximity of the brake pad wear sensor. The NFC circuit is configured to respond to the interrogation by the NFC device to transmit the NFC signal. The resonating component or the charge storage component has a physical condition or effective component value that is configured to be degraded in response to brake pad wear. The degradation of the resonating component or the charge storage component reducing the signal strength with which the NFC signal is transmitted. When a NFC or equivalent device has capability of determining the peak frequency response, then more accurate frequency determination method can be used.

### RELATED APPLICATION

This application claims the benefit of U.S. Provisional Application Ser. No. 62/385,573, filed on Sep. 9, 2016, the disclosure of which is incorporated herein by reference in its entirety.

### TECHNICAL FIELD

The invention relates generally to brake pad wear sensing systems and devices. More particularly, the invention relates to a brake pad wear sensor that measures wear in both inner and outer brake pads of a disc braking system.

### BACKGROUND

It is desirable to sense and inform the driver when automotive brake pads need to be replaced. Known electronic brake wear sensors have a resistor circuit sensor that is clipped to the inner brake pad. As the pad is abraded away by the rotor, the sensor is also abraded away, changing its resistance. A pigtail harness is connected to the sensor which is wired to a sensing module in the vehicle.

There are several problems with the known approach. The multiple wire harnesses required and the additional sensing module makes this an expensive solution. Routing of the harnesses through the vehicle suspension and the wheel/steering knuckle area is very challenging and prone to road debris abuse. Additionally, the wear sensor has to be replaced each time the pads are replaced, which can be expensive.

While employing electronic sensors to detect brake pad wear, it is important to consider that the brake pad and brake caliper area can reach temperatures in excess of 300 degrees C., which many electronic sensors cannot withstand.

From a cost and implementation standpoint, it is desirable to avoid using a wire harness, instead utilizing existing vehicle system components in order to reduce the cost of transporting the pad wear information to the driver display. It is also desirable that it not be necessary to replace the brake pad wear sensor with the brake pads when they are replaced. It is also desirable that the brake pad wear sensor provides diagnostic (e.g., heartbeat) capabilities, and the sensor must be capable of withstanding the extreme temperatures seen during braking.

Near-field communication (“NFC”) is a set of communication protocols that enable two electronic devices, one of which is usually a portable device such as a smartphone, to establish communication by bringing them within close proximity of each other.

Common smartphone uses for NFC devices include contactless payment systems, similar to those used in credit cards and electronic ticket smartcards and allow mobile payment to replace/supplement these systems. NFC can also be used for social networking, for sharing contacts, photos, videos or files. NFC-enabled devices can also act as electronic identity documents and keycards. NFC offers a low-speed connection with simple setup.

Like other “proximity card” technologies, NFC employs electromagnetic induction between two loop antennas when NFC-enabled devices, such as smartphones, to exchange information. NFC peer-to-peer communication enables two NFC-enabled devices to communicate with each other to exchange information in an ad hoc fashion.

NFC is a set of short-range wireless technologies, typically requiring a separation of 10 cm or less. NFC operates at 13.56 MHz on ISO/IEC 18000-3 air interface and at rates ranging from 106 kbit/s to 424 kbit/s. NFC always involves an initiator and a target. The initiator actively generates an RF field that can power a passive target. This enables NFC targets to take very simple form factors such as unpowered tags, stickers, key fobs, or cards. NFC peer-to-peer communication is possible, provided both devices are powered.

NFC tags contain data and are typically read-only, but may be writeable. They can be custom-encoded by their manufacturers or use NFC Forum specifications. The tags can securely store personal data such as debit and credit card information, loyalty program data, PINs and networking contacts, among other information. The NFC Forum defines four types of tags that provide different communication speeds and capabilities in terms of configurability, memory, security, data retention and write endurance.

As with proximity card technology, near-field communication uses electromagnetic induction between two loop antennas located within each other's near field, effectively forming an air-core transformer. It operates within the globally available and unlicensed radio frequency ISM band of 13.56 MHz. Most of the RF energy is concentrated in the allowed ±7 kHz bandwidth range, but the spectral mask for the main lobe is as wide as 1.8 MHz. The theoretical working distance for NFC with compact standard antennas is thought to be up to 20 cm (practical working distance of about 10 cm).

NFC communications can operate in a passive mode in which the initiator device provides a carrier field and the target device answers by modulating the existing field. In this mode, the target device may draw its operating power from the initiator-provided electromagnetic field, thus making the target device a transponder. In an active mode, both the initiator and target device communicate by alternately generating their own fields. A device deactivates its RF field while it is waiting for data. In this mode, both devices typically have power supplies.

### SUMMARY

Near field communication (“NFC”) has been widely used for communication between two electronic devices. For example, people exchange the files between iPad and iPhone through the NFC communication. With smartphones being so popular, NFC technology can be integrated in a brake pad wear sensing system. The brake pad wear sensor can include a NFC circuit and a pad wear sensor, such as a resistance sensor (e.g., a two stage resistance sensor). Alternatively, the brake pad wear sensor can be composed of one or more resonating components associated with the NFC circuit.

As the brake pad wears out at different stages, the NFC circuit range performance is degraded by decreasing resistance or by losing resonance. A user can use a smartphone or other electronic devices with NFC capability to diagnose the pad weariness through NFC. The information can be combined with the vehicle mileage information to predict the remaining life time of the pad.

According to one aspect, a brake pad wear measuring system is for use a floating caliper disc brake system including a piston supporting an inner brake pad and a floating caliper supporting an outer brake pad, wherein the piston and floating caliper move toward each other along a braking axis in response to application of the brake system so that the brake pads engage and apply a braking force to a brake rotor.

According to another aspect a brake pad wear sensing system for measuring brake pad wear for a vehicle disc brake system includes a brake pad wear sensor including a near field communication (“NFC”) circuit for transmitting an NFC signal and a tank circuit comprising a resonating component and a charge storage component. The tank circuit powers the brake pad wear sensor including the NFC circuit. The tank circuit is configured to be inductively charged in response to interrogation by a NFC device positioned within a predetermined proximity of the brake pad wear sensor. The NFC circuit is configured to respond to the interrogation by the NFC device to transmit the NFC signal. The resonating component or the charge storage component has a physical condition or effective component value that is configured to be degraded in response to brake pad wear, the degradation reducing the signal strength with which the NFC signal is transmitted.

According to another aspect, alone or in combination with any preceding aspect, the resonating component can include a plurality of resonating components that are configured to be destroyed sequentially in response to brake pad wear.

According to another aspect, alone or in combination with any preceding aspect, the resonating component can include a coil having an inductance configured to vary in response to brake pad wear.

According to another aspect, alone or in combination with any preceding aspect, the sensor can be configured so that the coil undergoes a physical change in response to brake pad wear, the inductance of the coil changing in response to the physical change in the coil.

According to another aspect, alone or in combination with any preceding aspect, the sensor can be configured so that the position of the coil relative to the brake rotor changes in response to brake pad wear, the effective inductance of the coil changing in response to the change in position of the coil relative to the brake rotor.

According to another aspect, alone or in combination with any preceding aspect, the charge storage component can include a plurality of charge storage components that are configured to be destroyed sequentially in response to brake pad wear.

According to another aspect, alone or in combination with any preceding aspect, the charge storage component can include a capacitor having a capacitance configured to vary in response to brake pad wear.

According to another aspect, alone or in combination with any preceding aspect, the sensor can be configured so that the capacitor undergoes a physical change in response to brake pad wear, the capacitance of the capacitor changing in response to the physical change in the capacitor.

According to another aspect, alone or in combination with any preceding aspect, the sensor can be configured so that the position of the capacitor relative to the brake rotor changes in response to brake pad wear, the effective capacitance of the capacitor changing in response to the change in position of the capacitor relative to the brake rotor.

According to another aspect, alone or in combination with any preceding aspect, the brake pad wear sensing system can also include an NFC device configured to interrogate the brake pad wear sensor and to interpret the signal strength of the NFC signal as being indicative of brake pad wear.

According to another aspect, alone or in combination with any preceding aspect, the NFC device can be an NFC enabled cell phone.

### BRIEF DESCRIPTION OF THE DRAWINGS

The foregoing and other features and advantages of the present invention will become apparent to those skilled in the art to which the present invention relates upon reading the following description with reference to the accompanying drawing, in which:

FIG. 1 is a schematic illustration of an example vehicle configuration showing disc brake components mounted on vehicle suspension components.

FIG. 2 is a schematic illustration depicting a brake wear sensor system implemented on an example disc brake configuration, wherein the disc brake is shown in a non-braking condition.

FIG. 3 is a schematic illustration depicting the brake wear sensor system of FIG. 2, wherein the disc brake is shown in a first braking condition with brake pads at a first level of wear.

FIG. 4 is a schematic illustration depicting the brake wear sensor system of FIG. 2, wherein the disc brake is shown in a second braking condition with brake pads at a second level of wear.

FIGS. 5-8 are schematic illustrations depicting different configuration of the brake wear sensor system.

FIG. 9 is a schematic illustration depicting alternative configurations of the brake wear sensor system.

FIG. 10 is a schematic illustration depicting one particular configuration of the brake wear sensor system.

FIGS. 11A and 11B are schematic illustrations depicting other particular configurations of the brake wear sensor system.

### DETAILED DESCRIPTION

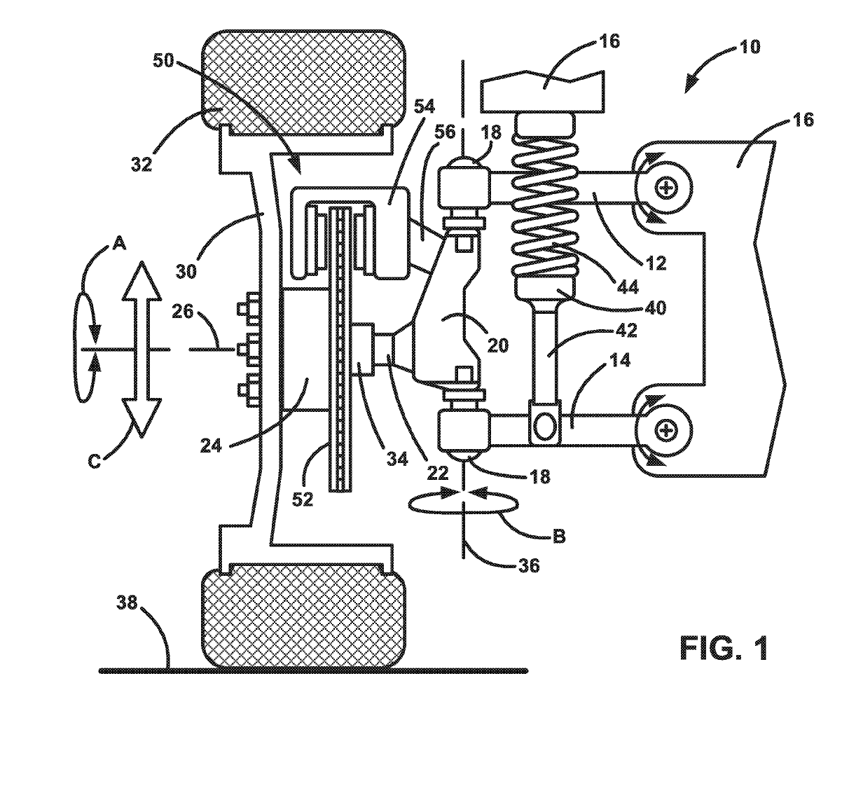

Referring to FIG. 1, an example vehicle suspension system 10 includes an upper control arm 12 and a lower control arm 14 that are connected to the vehicle 16 for pivoting movement. A steering knuckle 20 is connected to free ends of the control arms 12, 14 by ball joints or the like that permit relative movement between the knuckle and control arms. The steering knuckle 20 includes a spindle 22 that supports a wheel hub 24 for rotation (see arrow A) about a wheel axis 26. A wheel or rim 30 and tire 32 can be mounted on the wheel hub 24 by known means, such as lugs and lug nuts. The wheel hub 24 includes bearings 34 that facilitate rotation of the hub, rim 30, and tire 32 about the axis 26. The steering knuckle 20 is itself rotatable about a steering axis 36 (see arrow B) to steer the vehicle 16 in a known manner.

A damper 40, such as a shock absorber or strut, has a piston rod 42 connected to the lower control arm 14 and a cylinder 44 that is supported by structure of the vehicle 16, such as a vehicle frame-mounted bracket. The damper 40 dampens relative movement of the control arms 14, 16, and the steering knuckle 20 relative to the vehicle 16. The damper 40 can thus help dampen and absorb impacts between the road 38 and the tire 32, such as impacts with bumps, potholes, or road debris, that produce up and down movement (see arrow C) of the suspension system 10, the wheel 30, and the tire 32.

The vehicle 16 includes a disc braking system 50 that includes a brake disc 52 secured to the hub 24 for rotation with the hub, wheel 30, and tire 32. The disc braking system 50 also includes a brake caliper 54 that is secured to the steering knuckle 20 by a bracket 56. The disc 52 and the caliper 54 thus move in unison with the steering knuckle 20 through steering movements (arrow B) and suspension movements (arrow C). The disc 52 rotates (arrow A) relative to the caliper 54 and has an outer radial portion that passes through the caliper.

The configuration of the suspension system 10 shown in FIG. 1 is by way of example only and is not meant to limit the scope of the invention. The brake pad wear sensor system disclosed herein can be configured for utilization with any vehicle suspension configuration that implements disc brakes. For example, while the illustrated suspension system 10 is an independent front suspension, specifically an upper and lower control arm/A-arm (sometimes referred to as a double wishbone) suspension, other independent suspensions can be used. Examples of independent suspensions with which the brake pad wear sensing system can be implemented include, but are not limited to, swing axle suspensions, sliding pillar suspensions, MacPherson strut suspensions, Chapman strut suspensions, multi-link suspensions, semi-trailing arm suspensions, swinging arm suspensions, and leaf spring suspensions. Additionally, the brake pad wear sensing system can be implemented with dependent suspension systems including, but not limited to, Satchell link suspensions, Panhard rod suspensions, Watt's linkage suspensions, WOB link suspensions, Mumford linkage suspensions, and leaf spring suspensions. Furthermore, the brake pad wear sensing system can be implemented on front wheel disc brakes or rear wheel disc brakes.

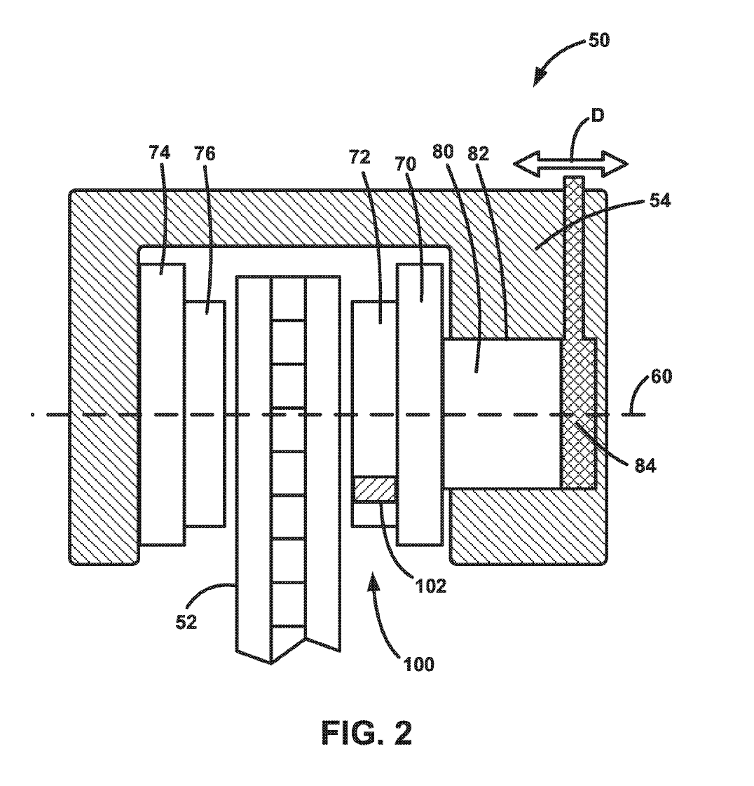

Referring to FIGS. 2-4, the disc braking system 50 is illustrated schematically and in greater detail. The brake system 50 is a single piston floating caliper system in which the connection of the caliper 54 to the vehicle 16 allows for axial movement of the caliper (“float”) relative to the brake disc 52. In this floating caliper configuration, the caliper 54 is permitted to move axially toward and away from the disc 52 (see arrow D) parallel to a braking axis 60.

The brake system 50 includes an inner brake pad holder 70 that supports an inner brake pad 72, and an outer brake pad holder 74 that supports an outer brake pad 76. The inner brake pad holder 70 is supported on a piston 80. The outer brake pad holder 74 is supported on the floating caliper 54. The piston 80 is disposed in a cylinder 82 that is supported on or formed in the floating caliper 54. Brake fluid 84 is pumped into the cylinder 82 in response to driver application of a brake pedal (not shown) in order to actuate the braking system 50.

The brake system 50 is maintained in the unactuated condition of FIG. 2 via bias applied by a biasing member (not shown), such as a spring. When the brake pedal is applied, the brake fluid 84 fills the cylinder 82 and applies fluid pressure to the piston 80, urging it to move to the left, as viewed in FIGS. 2-4. This causes the inner brake pad holder 70 and pad 72 to move along the braking axis 60 toward and the brake disc 52. The inner brake pad 72 engaging the disc 52 creates a reaction force that acts on the floating caliper 54, due to its supporting of the piston 80 and cylinder 82. Since the piston 80 is blocked against movement toward the disc 52 due to the engagement of the inner brake pad 72 with the disc, the brake fluid pressure in the cylinder 82 urges the floating caliper 54 to move to the right, as viewed in FIGS. 2-4. The floating caliper 54, moving to the right, causes the outer brake pad holder 74 and pad 76 to move along the braking axis 60 toward the brake disc 52. The inner pad 76 eventually engages the disc 52, which is now clamped between the inner and outer brake pads.

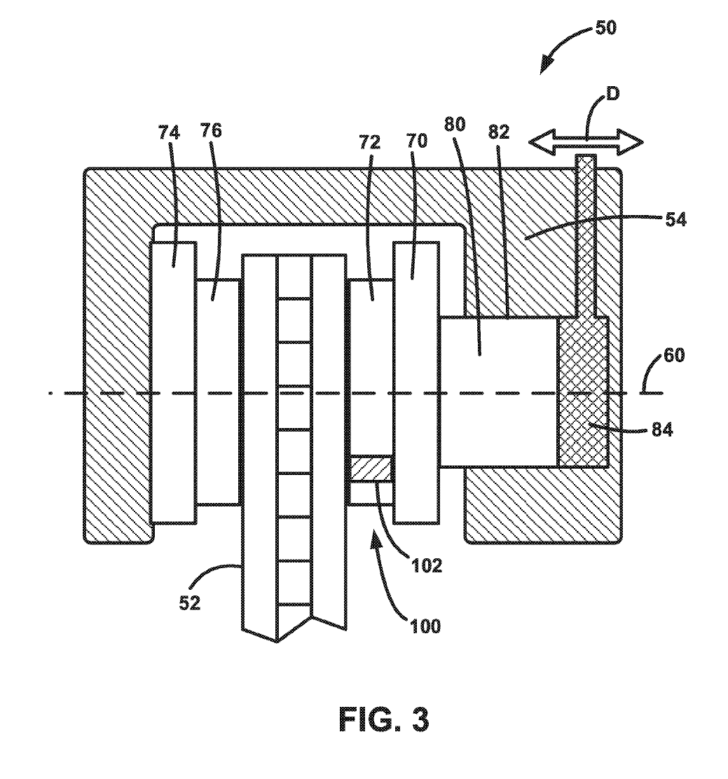

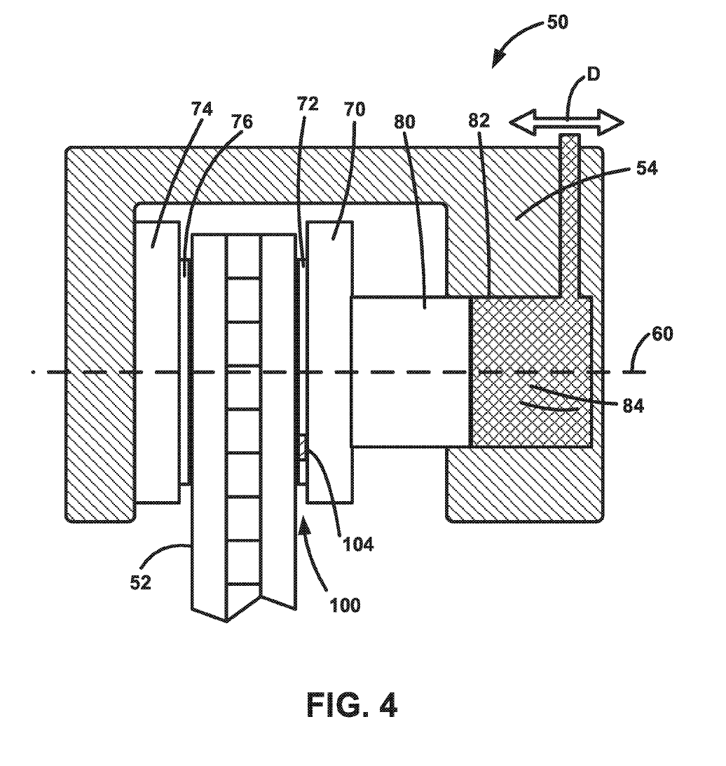

As the brake pads 72, 76 wear down, they become thinner. This is illustrated by comparing the brake pads 72, 76 of FIG. 3, which are fresh, thick, and unworn, to the brake pads of FIG. 4, which are old, thin, and worn-out. As seen in the comparison of FIGS. 3 and 4, owing to the floating caliper configuration of the brake system 50, both the piston 80 and the caliper 54 travel a greater distance when applying the worn pads of FIG. 4 than they do when applying the unworn pads.

A brake pad wear sensing system 100 measures the amount of wear on the brake pads 72, 76 directly via a sensor integrated within one of the pads. Wear on the pads is presumed to be even enough to allow the measurement of the wear on one pad to be indicative of the wear on both pads. Additionally, there is some built-in tolerance in the system 100 in that pads are considered worn well before they are at 100% worn.

Referring to FIGS. 2-4, the sensing system 100 includes a brake pad wear sensor 102 that is local to (built into) the inner brake pad 72. The sensor 102 is designed to wear away along with the brake pad 72. This wearing away of the sensor 102 can be associated with brake pad wear. The sensor 102 can have a variety of constructions. For example, the sensor 102 can be a resistive sensor in which the sensor includes one or more resistive elements. As the pad wears, the resistive element is also worn and its resistance/impedance changes, producing a change in the output of the sensor 102. This change in resistance/impedance is converted to data that is used to determine brake pad wear. In this configuration, the sensor 102 can include multiple resistive sensors, and brake pad wear can be measured in stages as the resistive sensors are destroyed sequentially as the pad wears. Alternatively, the resistive sensor can be configured so that its resistance changes gradually in response to pad wear, and this gradual change can be sensed as gradual pad wear.

Alternatively, the sensor 102 can be a capacitive sensor in which the sensor includes a capacitor element. As the pad wears, the capacitor element wears and its capacitance changes, producing a change in the output of the sensor 102. This change in capacitance is converted to data that is used to determine brake pad wear. In this configuration, the sensor 102 can include multiple capacitive sensors, and brake pad wear can be measured in stages as the capacitive sensors are destroyed sequentially as the pad wears.

Similarly, the sensor 102 can be an inductive sensor in which the sensor includes inductor coil elements. As the pad wears, the inductor coils wears and its inductance changes, producing a change in the output of the sensor 102. This change in inductance is converted to data that is used to determine brake pad wear. In this configuration, the sensor 102 can include multiple inductor coil elements, and brake pad wear can be measured in stages as the coil elements are destroyed sequentially as the pad wears.

From the above, it can be seen that brake pad wear is sensed through the wear and/or destruction of the sensor elements of the brake pad wear sensor 102. In all of these configurations, this wear can be sensed using near field communication (“NFC”). The NFC communication configuration can be built into the sensor 102 itself, or it can be separate from the sensor, and wired to external NFC communication hardware.

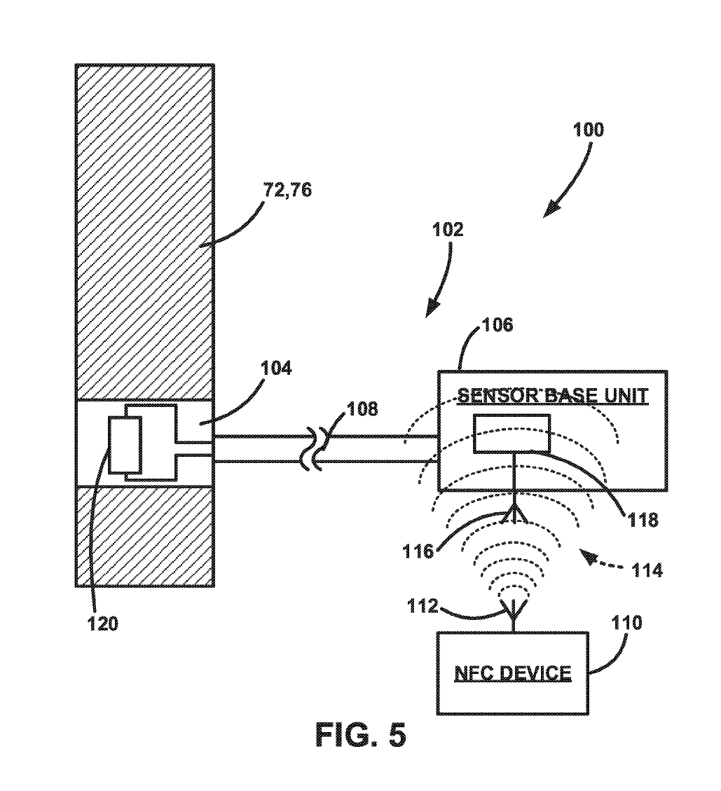

Referring to FIG. 5, according to one configuration, the sensing system 100 includes a brake pad wear sensor 102. The wear sensor 102 includes a sensor head 104 that is local to (built-into) the inner brake pad 72 and a remote sensor base unit 106. The sensor head 104 includes a sensor element 120, such as a resistive element, a capacitive element, or an inductive element, that wears with the brake pad and produces a signal commensurate with brake pad wear, as described above. The sensor head 104 is connected to the sensor base unit 106 by a cable 108, which is built to withstand the high temperature environment of the brake system 50. The sensor head 104 is disposable with the worn pad 72. The base unit 106 and cable 108 are re-usable.

To detect the condition of the brake pad 72, the wear sensor 102 is interrogated with an NFC device 110, such as a smart phone. The NFC communication proceeds in a known manner by positioning the NFC device 110 in close proximity to the brake pad wear sensor 102. The NFC device 110 includes an antenna/coil 112 that generates an electromagnetic field 114, which acts on the sensor base unit 106 and induces a current in a coil/antenna 116 of the base unit. The current induced in the base unit 106 provides power to the sensor 102 with which the sensor head 104 can be interrogated to determine the amount of wear on the brake pad 72.

The sensor head 104 is designed to wear away along with the brake pad. This wearing away of the sensor head can be associated with brake pad wear. In one example configuration, the sensor has active components. In this configuration, the base unit 106 can include sensor electronics 118, such as a controller and other associated NFC components, which can calculate brake pad wear and transmit that information to the NFC device 110. In another configuration, the sensor 102 is a passive device, omitting the sensor electronics 118. In this configuration, the sensor 102 responds to interrogation with a signal having characteristics, such as strength or amplitude, that vary with the amount of wear on the sensor. For example, where the sensor element is an array of resistive elements, such as multiple resistors in parallel, the reduction in resistance produced by brake pad wear increases the load of the 116 antenna. It produces a corresponding change in the signal produced by the antenna/coil 116 when the sensor is interrogated by the NFC device 110. The NFC device 110 can process the signal received from the wear sensor 102 and associate the characteristic, e.g., signal strength, with a corresponding degree of brake pad wear.

The NFC device 110 can implement intelligent judgment to enhance or better utilize the brake pad wear data obtained from the sensor 102. For example, the NFC device 110 can utilize past brake pad wear measurements, vehicle mileage information (e.g., miles on pads), and brake pad age information to performed an informed calculation of brake pad wear. This information can be obtained in a variety of manners, such as through queries requiring that the information be input as a prerequisite for pad wear calculation, or automatically through communication between the NFC device 110 and vehicle control systems, such as a body control module (“BCM”).

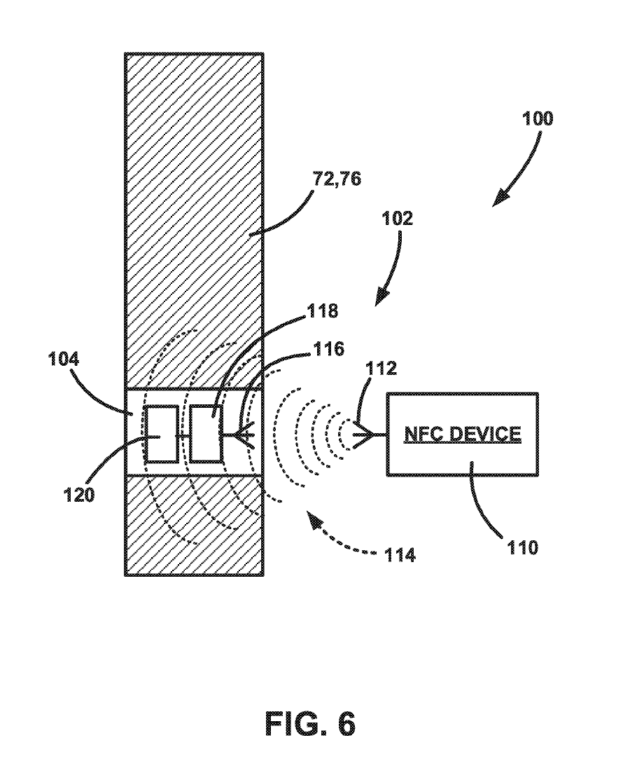

Referring to FIG. 6, according to another configuration, the sensing system 100 omits the separate sensor base unit and instead includes a unitary brake pad wear sensor 102. The wear sensor 102 includes a sensor head 104 that is local to (built-into) the inner brake pad 72 and includes all components of the brake pad wear sensor 102. The sensor head 104 includes a sensor element 120, such as a resistive element, a capacitive element, or an inductive element, that wears with the brake pad and produces a signal commensurate with brake pad wear, as described above. Depending on its configuration, the sensor 102 can also include sensor electronics 118, such as a controller and other associated components, that are operatively connected to an antenna/coil 116. The entire sensor 102 can be disposable, or the sensor can be a two piece component in which the sensor element 120 is disposable with the brake pad, and the antenna 116 and sensor electronics 118 are mounted in a separate housing and are detachable and re-usable.

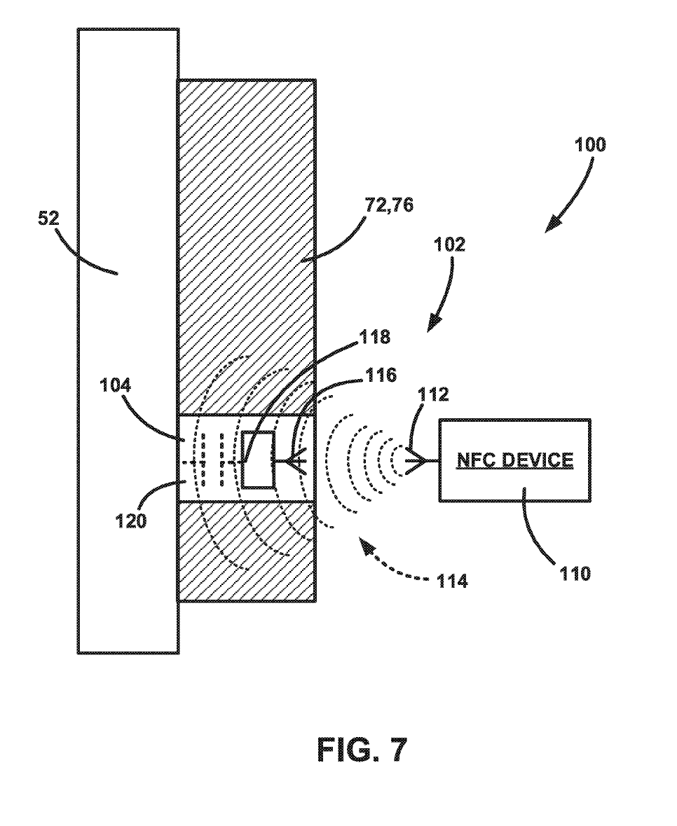

Another configuration is shown in FIG. 7. In FIG. 7, sensor element 120 is a parasitic capacitance existing between a capacitive element 118 and the brake rotor 52. As the brake pad 72 wears, the distance between the element 118 and metal brake rotor 52 becomes less and the parasitic capacitance of the sensor element 120 is increased. This change alters the antenna 116 resonating frequency which will affect NFC communication range. Because, in this configuration, the sensor element 120 produces a change in sensor output in response to the change in relative position between the rotor 52 and the capacitive element 118, sensor replacement is not required when changing the brake pad 72, as no part of the sensor 102 is destroyed during use.

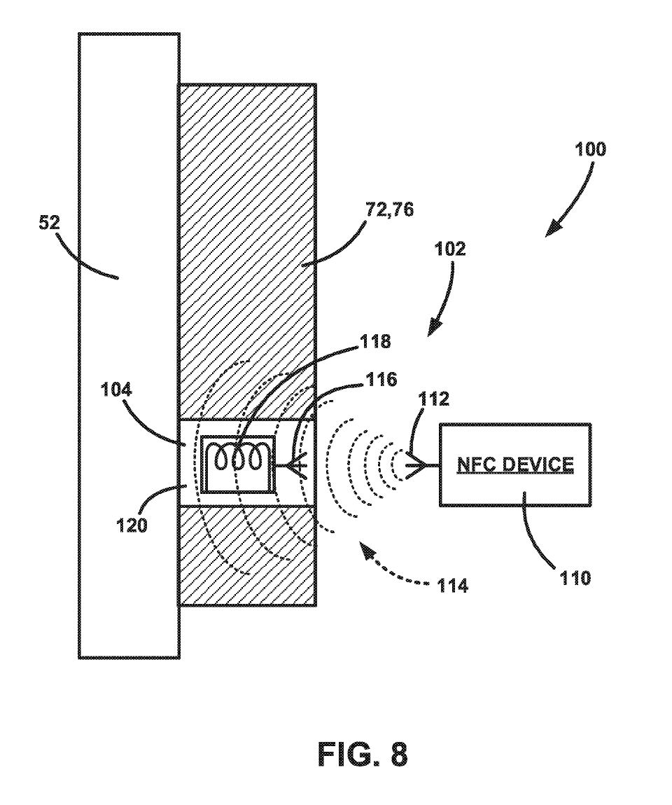

Referring to FIG. 8, in a manner similar to that described in reference to the example configuration of FIG. 7, passive inductance can also be used to sense brake pad wear in a manner in which no new sensor is required when changing the brake pad. Referring to FIG. 8, the sensor element 120 is the equivalent inductance coupling (associated with the magnetic field) between the coil 118 and the metal rotor 52. The current induced by the NFC device 110 (e.g., cell phone) flows through the coil 118. Then the induced current generates the magnetic field. This magnetic field reaches the surface of the metal brake rotor 121 and generates the eddy current. The eddy current generated on the metal brake rotor surface regenerates the magnetic field to counter the field produced by the coil 118. This results in the inductance reduction of the original coil 118 and it changes the antenna 116 resonating frequency and amplitude.

As the brake pad 72 wears, the distance between the coil element 118 and the rotor 52 surface is reduced. This is equivalent to a strong coupling factor to the sensor element 120, and the coil 118 inductance is further reduced. This reduces the NFC communication range. Additionally, the NFC device 10 can have the capability to sense the signal level from the sensor 102 via frequency sweep. In this configuration, the resonating frequency of the sensor element d120 can be determined. For example, the NFC device 110 can emit the interrogation signal 114 at different frequencies and looks for response signal levels from the brake pad wear sensor 102. Based on the signal level of the received response, the NFC device 110 can identify the resonating frequency of the sensor 102. In this manner, the accuracy of the determined brake pad wear can be improved over measurements taken at just one frequency.

To detect the condition of the brake pad 72, the wear sensor 102 is interrogated with an NFC device 110, such as a smart phone. The NFC communication proceeds in a known manner by positioning the NFC device 110 in close proximity to the sensor head 104. The NFC device 110 includes an antenna/coil 112 that generates an electromagnetic field 114, which acts on the sensor head 104 and induces a current in a coil/antenna 116 of the base unit. The current induced in the base unit 106 provides power to the sensor 102.

In one example configuration, the sensor has active components. In this configuration, the sensor head 104 can include sensor electronics 118, such as a controller and other associated NFC components, which can calculate brake pad wear and transmit that information to the NFC device 110. In another configuration, the sensor 102 is a passive device, omitting the sensor electronics 118. In this configuration, the sensor 102 responds to interrogation with a signal having characteristics, such as strength or amplitude or even frequency, that vary with the amount of wear on the sensor. For example, where the sensor element is a resistive element, the reduction in resistance produced by brake pad wear also produces a corresponding change in the signal produced by the antenna/coil 116 when the sensor is interrogated by the NFC device 110. The NFC device 110 can process the signal received from the wear sensor 102 and associate the characteristic, e.g., signal strength, with a corresponding degree of brake pad wear.

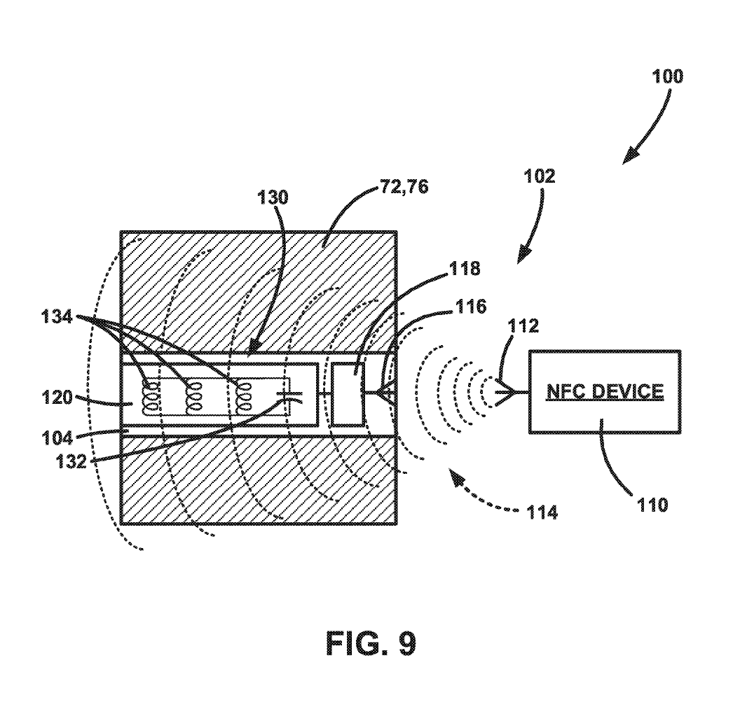

Example configurations of the brake pad wear sensor 102 are illustrated in FIGS. 9-11. The example configurations are illustrated as being implemented in a sensor configuration in which the sensor is a unitary device installed on the brake pad, omitting the cable 108 and base unit 106, i.e., as illustrated in FIG. 6. Those skilled in the art will appreciate, however, that these brake pad wear sensor configurations can also be implemented in a sensor configuration in which a sensor head is connected to a sensor base unit via a cable, i.e., as illustrated in FIG. 5.

Referring to FIG. 9, the brake pad wear sensor 102 includes a sensor head 104 including a sensor element 120. The sensor element includes sensor electronics 118, including NFC components, and an antenna 116 for facilitating communication between the wear sensor 102 and an NFC device 110. In the example configuration of the wear sensor 102 illustrated in FIG. 9, the sensor element 120 includes a tank circuit 130 including a charge storage component 132, such as a capacitor, and one or more resonating components 134, such as inductor coils. In the example configuration of FIG. 9, there are three resonating components 134. The sensor element 120 could, however, include any number of resonating components 134, i.e., one or more.

When the NFC device 110 generates the electromagnetic field 114 to interrogate the wear sensor 102, the resonating components 134 respond by generating an induced current, which wakes and activates the NFC sensor components 118. The wear sensor 102 responds to interrogation by the NFC device 110 by providing a response signal. The strength of the response signal is related to the induced current generated by the resonating components 134.

As the brake pad 72 wears, the resonating components 134 are destroyed sequentially. Each time a resonating component 134 is destroyed, the signal strength of the response signal that the wear sensor 102 transmits to the NFC device 110 is reduced. The NFC device 110 can interpret this degradation in signal strength to be indicative of the amount of wear on the brake pad 72. As the brake pad 72 wears further, additional resonating components 134 will be destroyed, further degrading the response signal. The NFC device 110 can interpret this further signal strength degradation as further brake pad wear. The example configuration of FIG. 9 thus illustrates a sensor 102 that can indicate four levels of brake pad wear:
Little or no wear (all three resonating components 134 intact):
Slight wear (two resonating components 134 intact);
Medium wear (one resonating component 134 intact); and
Pad worn out (zero resonating components 134 intact).

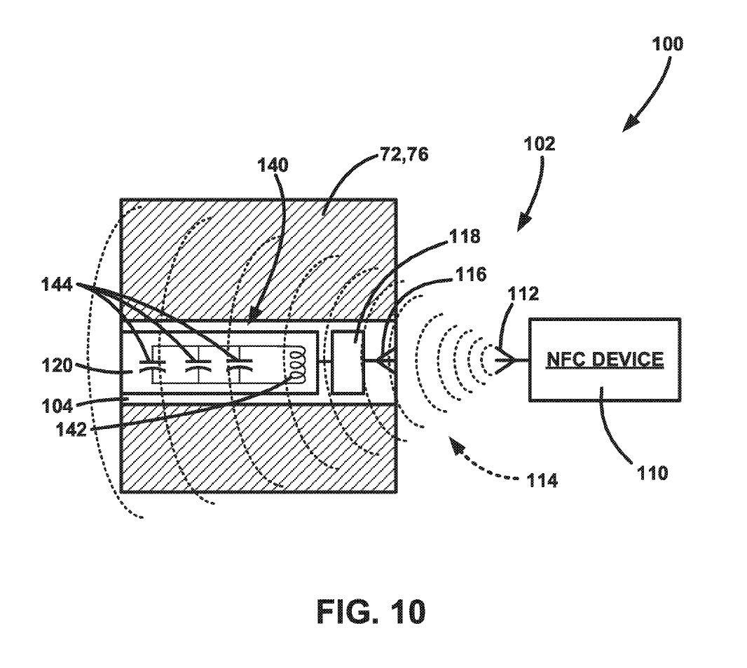

Another example configuration is illustrated in FIG. 10. Referring to FIG. 10, the brake pad wear sensor 102 includes a sensor head 104 including a sensor element 120. The sensor element includes sensor electronics 118, including NFC components, and an antenna 116 for facilitating communication between the wear sensor 102 and an NFC device 110. In the example configuration of the wear sensor 102 illustrated in FIG. 10, the sensor element 120 includes a tank circuit 140 including a resonating component 142, such as an inductor coil, and one or more charge storage components 144, such as capacitors. In the example configuration of FIG. 10, there are three charge storage components 144. The sensor element 120 could, however, include any number of charge storage components 144, i.e., one or more.

When the NFC device 110 generates the electromagnetic field 114 to interrogate the wear sensor 102, the resonating component 142 responds by generating an induced current, which wakes and activates the NFC sensor components 118. The wear sensor 102 responds to interrogation by the NFC device 110 by providing a response signal. The strength of the response signal is related to the capacitance of the charge storage components 144.

As the brake pad 72 wears, the charge storage components 144 are destroyed sequentially. Each time a charge storage component 144 is destroyed, the capacitance of the circuit decreases, which reduces the signal strength of the response signal that the wear sensor 102 transmits to the NFC device 110. The NFC device 110 can interpret this degradation in signal strength to be indicative of the amount of wear on the brake pad 72. As the brake pad 72 wears further, additional charge storage components 144 will be destroyed, further degrading the response signal. The NFC device 110 can interpret this further signal strength degradation as further brake pad wear. The example configuration of FIG. 10 thus illustrates a sensor 102 that can indicate four levels of brake pad wear:
Little or no wear (all three charge storage components 144 intact):
Slight wear (two charge storage components 144 intact);
Medium wear (one charge storage component 144 intact); and
Pad worn out (zero charge storage components 144 intact).

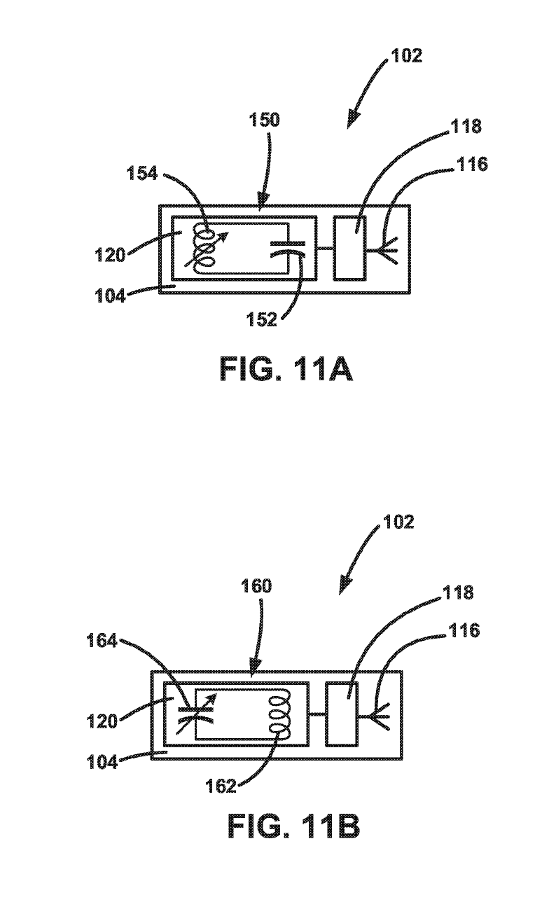

Another example configuration is illustrated in FIG. 11A. The example configuration of FIG. 11A is similar to the example configuration of FIG. 9 in the sense that a change in inductance is used to trigger a change in sensor signal strength commensurate with brake pad wear. Referring to FIG. 11A, the brake pad wear sensor 102 includes a sensor head 104 including a sensor element 120. The sensor element includes sensor electronics 118, including NFC components, and an antenna 116 for facilitating communication between the wear sensor 102 and an NFC device. In the example configuration of the wear sensor 102 illustrated in FIG. 11A, the sensor element 120 includes a tank circuit 150 including a charge storage component 152, such as a capacitor, and a variable resonating component 154, such as a variable inductor coil. By “variable,” it is meant that the inductance can be changed through physically altering the inductor coil through wear, or by altering the surroundings of the inductor coil, thereby effectively changing its inductance.

When the NFC device 110 generates the electromagnetic field 114 to interrogate the wear sensor 102, the variable resonating component 154 responds by generating an induced current, which wakes and activates the NFC sensor components 118. The wear sensor 102 responds to interrogation by the NFC device 110 by providing a response signal. The strength of the response signal is related to the inductance of the variable resonating component 154.

As the brake pad 72 wears, the inductance of the variable resonating component 154 changes, i.e., is reduced, in response to either being worn down or through changes in its surroundings, such as by moving closer to the comparatively large metal mass of the brake rotor. This reduces the signal strength of the response signal that the wear sensor 102 transmits to the NFC device. The NFC device can interpret this degradation in signal strength to be indicative of the amount of wear on the brake pad. As the brake pad wears further, the inductance of the variable resonating component 154 will be further reduced, which further degrades the response signal. The NFC device can interpret this further signal strength degradation as further brake pad wear.

Another example configuration is illustrated in FIG. 11B. The example configuration of FIG. 11B is similar to the example configuration of FIG. 10 in the sense that a change in capacitance is used to trigger a change in sensor signal strength commensurate with brake pad wear. Referring to FIG. 11B, the brake pad wear sensor 102 includes a sensor head 104 including a sensor element 120. The sensor element includes sensor electronics 118, including NFC components, and an antenna 116 for facilitating communication between the wear sensor 102 and an NFC device. In the example configuration of the wear sensor 102 illustrated in FIG. 9B, the sensor element 120 includes a tank circuit 160 including a resonating component 162, such as an inductor coil, and a variable charge storage component 164, such as a variable capacitor. By “variable,” it is meant that the capacitance can be changed through physically altering the capacitor through wear, or by altering the surroundings of the capacitor, thereby effectively changing its capacitance.

When the NFC device 110 generates the electromagnetic field 114 to interrogate the wear sensor 102, the resonating component 162 responds by generating an induced current, which wakes and activates the NFC sensor components 118. The wear sensor 102 responds to interrogation by the NFC device 110 by providing a response signal. The strength of the response signal is related to the capacitance of the charge storage component 164.

As the brake pad 72 wears, the capacitance of the variable charge storage component 164 changes, i.e., is reduced, in response to either being worn down or by moving closer to the comparatively large metal mass of the brake rotor. As a result, the capacitance of the circuit decreases, which reduces the signal strength of the response signal that the wear sensor 102 transmits to the NFC device. The NFC device can interpret this degradation in signal strength to be indicative of the amount of wear on the brake pad. As the brake pad wears further, the capacitance of the variable charge storage components 164 will be further reduced, which further degrades the response signal. The NFC device can interpret this further signal strength degradation as further brake pad wear.

From the above description of the invention, those skilled in the art will perceive improvements, changes and modifications. Such improvements, changes and modifications within the skill of the art are intended to be covered by the appended claims.

We claim:

1. A brake pad wear sensing system for measuring brake pad wear for a vehicle disc brake system, the brake pad wear measuring system comprising:
a brake pad wear sensor comprising:
a near field communication (“NFC”) circuit for transmitting an NFC signal; and
a tank circuit comprising a resonating component and a charge storage component, the tank circuit powering the brake pad wear sensor including the NFC circuit,
wherein the tank circuit is configured to be inductively charged in response to interrogation by a NFC device positioned within a predetermined proximity of the brake pad wear sensor,
wherein the NFC circuit is configured to respond to the interrogation by the NFC device to transmit the NFC signal, and
wherein the resonating component or the charge storage component has a physical condition or effective component value that is configured to be degraded in response to brake pad wear, the degradation reducing the signal strength with which the NFC signal is transmitted.

2. The brake pad wear sensing system recited in claim 1, wherein the resonating component comprises a plurality of resonating components that are configured to be destroyed sequentially in response to brake pad wear.

3. The brake pad wear sensing system recited in claim 1, wherein the resonating component comprises a coil having an inductance configured to vary in response to brake pad wear.

4. The brake pad wear sensing system recited in claim 3, wherein the sensor is configured so that the coil undergoes a physical change in response to brake pad wear, the inductance of the coil changing in response to the physical change in the coil.

5. The brake pad wear sensing system recited in claim 3, wherein the sensor is configured so that the position of the coil relative to the brake rotor changes in response to brake pad wear, the effective inductance of the coil changing in response to the change in position of the coil relative to the brake rotor.

6. The brake pad wear sensing system recited in claim 1, wherein the charge storage component comprises a plurality of charge storage components that are configured to be destroyed sequentially in response to brake pad wear.

7. The brake pad wear sensing system recited in claim 1, wherein the charge storage component comprises a capacitor having a capacitance configured to vary in response to brake pad wear.

8. The brake pad wear sensing system recited in claim 7, wherein the sensor is configured so that the capacitor undergoes a physical change in response to brake pad wear, the capacitance of the capacitor changing in response to the physical change in the capacitor.

9. The brake pad wear sensing system recited in claim 7, wherein the sensor is configured so that the position of the capacitor relative to the brake rotor changes in response to brake pad wear, the effective capacitance of the capacitor changing in response to the change in position of the capacitor relative to the brake rotor.

10. The brake pad wear sensing system recited in claim 1, further comprising an NFC device configured to interrogate the brake pad wear sensor and to interpret the signal strength of the NFC signal as being indicative of brake pad wear.

11. The brake pad wear sensing system recited in claim 6, wherein the NFC device comprises an NFC enabled cell phone.
